(19) United States
(12) Patent Application Publication
(10) Pub. No.: US 2025/0065474 A1
(43) Pub. Date: Feb. 27, 2025

(54) JIG FOR INSPECTING CASSETTE, CASSETTE MODULE INCLUDING THE SAME AND METHOD OF INSPECTING CASSETTE USING THE SAME

(71) Applicant: SAMSUNG DISPLAY CO., LTD., YONGIN-SI (KR)

(72) Inventors: HYUN-HOO SEO, Yongin-si (KR); MINCHUL JUNG, Yongin-si (KR); BYUNG-BOO CHOI, Yongin-si (KR)

(21) Appl. No.: 18/631,143

(22) Filed: Apr. 10, 2024

(30) Foreign Application Priority Data
Aug. 22, 2023 (KR) 10-2023-0109881

(51) Int. Cl. B25B 11/02

(52) U.S. Cl. CPC B25B 11/02

(57) ABSTRACT

A jig for inspecting a cassette includes a first frame, a second frame connected to the first frame and extending from the first frame in a first direction, a first positioning member extending from an upper surface of the first frame in the first direction, wherein the first positioning member includes a first side surface connected to the second frame and a second side surface at which a groove is defined, and a second positioning member connected to the second surface of the first positioning member and movable along the groove.

### CROSS-REFERENCE TO RELATED APPLICATION(S)

This application claims priority under 35 USC § 119 to Korean Patent Application No. 10-2023-0109881 filed on Aug. 22, 2023, in the Korean Intellectual Property Office (KIPO), the entire disclosure of which is incorporated by reference herein.

### BACKGROUND

### 1. Field

Embodiments relate to a jig for inspecting a cassette, more specifically, a jig for inspecting a cassette, a cassette module including the jig, and a method of inspecting a cassette using the jig.

### 2. Description of the Related Art

A display device may be manufactured through processes performed in different spaces. In this case, a cassette that accommodates a substrate may be used to transport or store a substrate of the display device during a manufacturing process. The cassette that accommodates the substrate may provide a space for stacking a plurality of substrates. The plurality of substrates may be inserted into the cassette for storage. Each of the plurality of substrates in the cassette may be withdrawn by a hand of a transfer robot.

### SUMMARY

Embodiments provide a jig for inspecting a cassette that improves process efficiency.

Embodiments provide a cassette module including the jig.

Embodiments provide a method of inspecting a cassette using the jig.

According to an embodiment of the present disclosure, a jig for inspecting a cassette includes a first frame, a second frame connected to the first frame and extending from the first frame in a first direction, a first positioning member extending from an upper surface of the first frame in the first direction, wherein the first positioning member includes a first side surface connected to the second frame and a second side surface at which a groove is defined, and a second positioning member connected to the second surface of the first positioning member and movable along the groove.

In an embodiment, the jig may further include a first fixing member protruding from a lower surface of the first frame in a direction opposite to the first direction, and a second fixing member coupled to the second frame and movable in the first direction or in the direction opposite to the first direction.

In an embodiment, the second positioning member may include a moving member movable in a second direction intersecting the first direction or in a direction opposite to the second direction, and a measuring member coupled to the moving member.

In an embodiment, the groove may include a moving groove extending in the first direction, and a plurality of fixing grooves extending from the moving groove in a second direction intersecting the first direction, and spaced apart from each other along the first direction.

According to an embodiment of the present disclosure, a cassette module includes a cassette including a first plate and a second plate spaced apart from the first plate in a first direction and facing the first plate, and defining a plurality of slots between the first plate and the second plate, and a jig for inspecting the cassette extending in the first direction, and detachably coupled to each of the first plate and the second plate.

In an embodiment, the jig may include a first frame detachably coupled to the first plate, and a second frame connected to the first frame, extending from the first frame in the first direction, and detachably coupled to the second plate.

In an embodiment, the jig may further include a first fixing member protruding from a lower surface of the first frame in a direction opposite to the first direction. The first frame may be coupled to the first plate through the first fixing member.

In an embodiment, the jig may further include a second fixing member coupled to the second frame and movable in the first direction or in a direction opposite to the first direction. The second frame may be coupled to the second plate through the second fixing member.

In an embodiment, the jig may further include a first positioning member extending from an upper surface of the first frame in the first direction, wherein the first positioning member includes a first side surface connected to the second frame and a second side surface at which a groove is defined, and defining a groove, and a second positioning member connected to the second side surface of the first positioning member and movable along the groove.

In an embodiment, the groove may include a moving groove extending in the first direction, and a plurality of fixing grooves extending from the moving groove in a second direction intersecting the first direction, and spaced apart from each other along the first direction.

In an embodiment, the plurality of fixing grooves may be spaced apart at regular intervals along the first direction, and positions of the plurality of fixing grooves may correspond to positions of the plurality of slots, respectively.

In an embodiment, the second positioning member may include a moving member movable in a second direction intersecting the first direction or in a direction opposite to the second direction, and a measuring member coupled to the moving member.

According to an embodiment of the present disclosure, a method of inspecting a cassette according to an embodiment of the present disclosure includes coupling a first frame of a jig for inspecting the cassette to a first plate of the cassette defining a plurality of slots, coupling a second frame of the jig to a second plate of the cassette spaced apart from the first plate in a first direction, moving a positioning member of the jig to a measurement position, and measuring a sagging of a substrate accommodated in one of the plurality of slots of the cassette using the jig.

In an embodiment, the jig may include a first fixing member protruding in a direction opposite to the first direction. In the coupling of the first frame to the first plate, the first frame may be coupled to the first plate through the first fixing member.

In an embodiment, the jig may include a second fixing member coupled to the second frame and movable in the first direction or in a direction opposite to the first direction. In the coupling of the second frame to the second plate, the second frame may be coupled to the second plate through the second fixing member.

In an embodiment, the positioning member may include a first positioning member extending in the first direction and defining a groove, and a second positioning member connected to the first positioning member and movable along the groove. The groove may include a moving groove extending in the first direction, and a plurality of fixing grooves extending from the moving groove in a second direction intersecting the first direction, and spaced apart from each other along the first direction.

In an embodiment, the moving of the positioning member to the measurement position may include moving the second positioning member in the first direction or in a direction opposite to the first direction through the first positioning member.

In an embodiment, the moving of the second positioning member in the first direction or in the direction opposite to the first direction may include moving the second positioning member along the moving groove of the first positioning member, and moving and fixing the second positioning member to one of the plurality of fixing grooves of the first positioning member.

In an embodiment, the second positioning member may include a moving member movable in the second direction or in a direction opposite to the second direction, and a measuring member coupled to the moving member. The moving of the positioning member to the measurement position may further include moving the measuring member in the second direction through the moving member.

In an embodiment, in the measuring of the sagging of the substrate accommodated in the plurality of slots of the cassette using the jig, the sagging of the substrate may be measured through the measuring member.

In a cassette module according to embodiments of the present disclosure, the cassette module may include a cassette and a jig for inspecting the cassette that is detachable from the cassette. Frames of the jig may be coupled to the cassette, respectively, and a positioning member of the jig may be easily moved to a measurement position. When a problem (e.g., substrate damage) occurs in a substrate accommodated in the cassette, the jig may be coupled to the cassette to accurately measure a sagging amount of the substrate. Accordingly, a cause of the problem may be clearly and quickly identified, and reliability and convenience in the process may be improved.

### BRIEF DESCRIPTION OF THE DRAWINGS

FIG. 1 is a perspective view of a cassette module according to an embodiment of the present disclosure.

FIGS. 2 and 3 are views illustrating a jig for inspecting a cassette included in the cassette module of FIG. 1.

FIGS. 4, 5, 6, 7, 8, 9, 10 and 11 are views illustrating a method of inspecting a cassette according to an embodiment of the present disclosure.

### DETAILED DESCRIPTION OF THE EMBODIMENTS

Hereinafter, embodiments of the present disclosure will be described in more detail with reference to the accompanying drawings. The same reference numerals are used for the same components in the drawings, and redundant descriptions of the same components will be omitted.

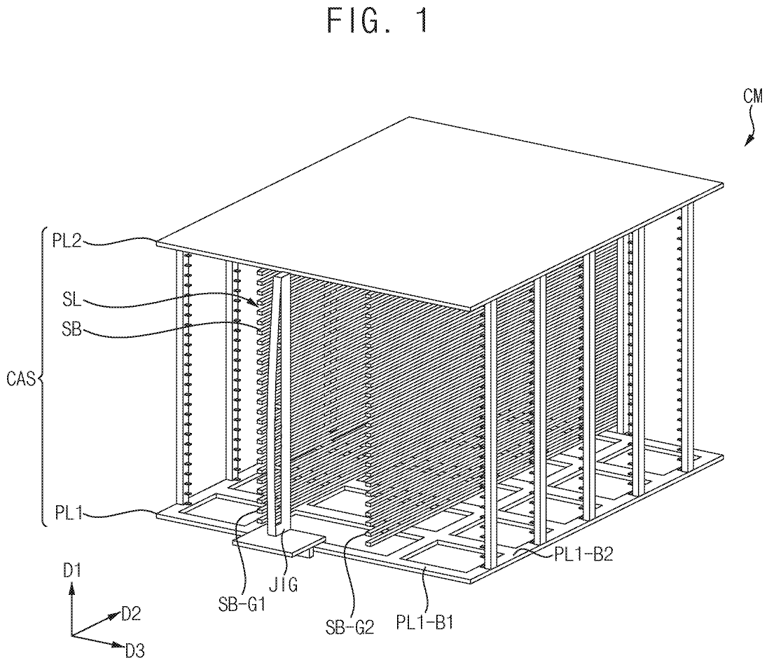

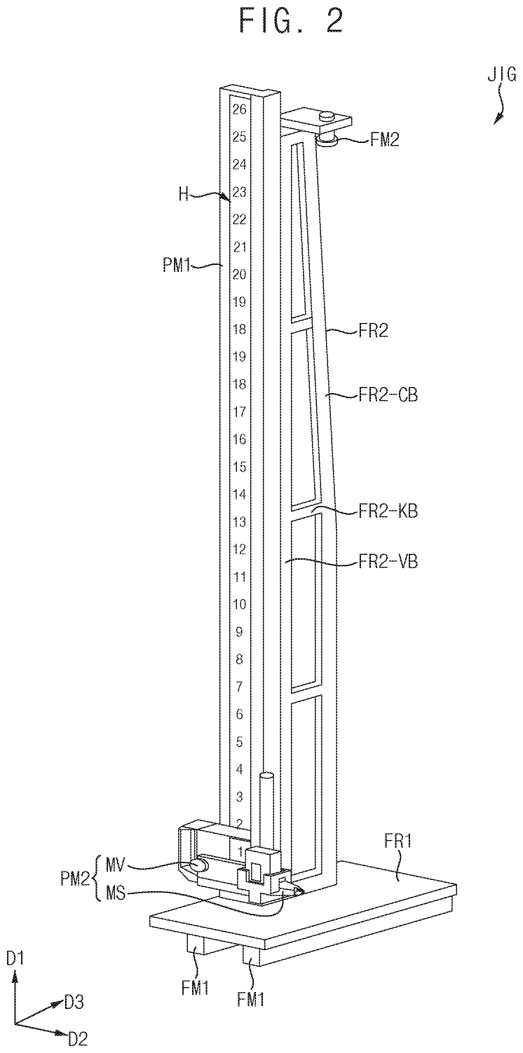

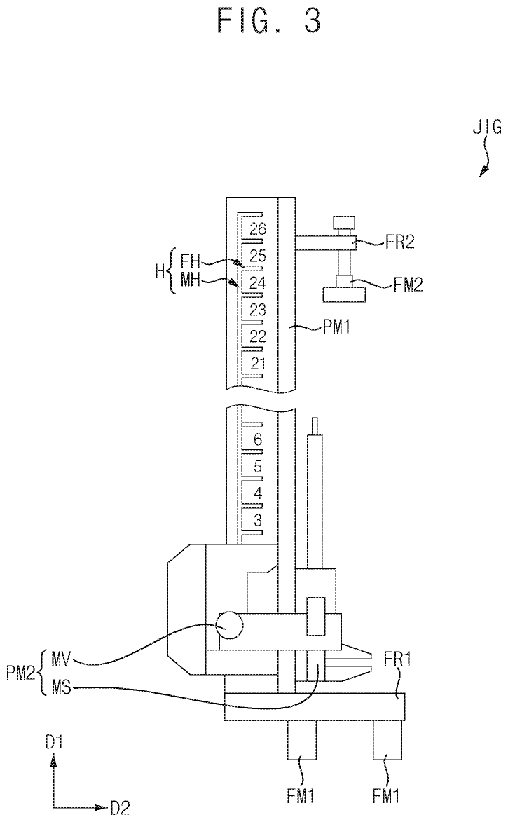

FIG. 1 is a perspective view of a cassette module according to an embodiment of the present disclosure. FIGS. 2 and 3 are views illustrating a jig for inspecting a cassette included in the cassette module of FIG. 1.

Referring to FIGS. 1, 2, and 3, a cassette module CM may include a cassette CAS and a jig JIG for inspecting a cassette.

The cassette CAS may include a first plate PL1 and a second plate PL2. The second plate PL2 may be spaced apart from the first plate PL1 in a first direction D1. Each of the first plate PL1 and the second plate PL2 may be parallel to a plane defined by a second direction D2 intersecting the first direction D1 and a third direction D3 intersecting each of the first direction D1 and the second direction D2. For example, the first direction D1, the second direction D2, and the third direction D3 may be perpendicular to each other. The first plate PL1 and the second plate PL2 may face each other in the first direction D1. In an embodiment, each of the first and second plates PL1 and PL2 may be of a rectangular shape or a square shape. In an embodiment, the second plate PL1 may have a rectangular plate or a square plate, and the first plate PL1 may include a meshed pattern to define a plurality of first bars PL1-B1 extending in the third direction D3 and a plurality of second bars PL1-B2 extending in the second direction D2. The present disclosure is not limited thereto. In an embodiment, the first and second plates PL1 and PL2 may have the same shape and area. In an embodiment, the first and second plates PL1 and P12 may have the same shape, and the first plate PL1 may have an area larger than the second plate PL2.

The cassette CAS may further include a plurality of support bars SB. The support bars SB may be disposed between the first plate PL1 and the second plate PL2. For example, the support bars SB may extend lengthwise in the second direction D2 and may be arranged to be spaced apart from each other in the first direction D1. However, the present disclosure is not limited thereto, and the support bars SB may extend in the first direction D1, and may be arranged to be spaced apart from each other in the second direction D2. In addition, the support bars SB may be arranged in two rows between the first plate PL1 and the second plate PL2. However, the present disclosure is not limited thereto, and the support bars SB may be arranged in one row or three or more rows.

The cassette CAS may define a plurality of slots SL between the first plate PL1 and the second plate PL2. Specifically, the support bars SB, which are spaced apart from each other in the first direction D1, may define the slots SL. A plurality of substrates may be accommodated in the slots SL, respectively. That is, the substrates may be accommodated in spaces in which the support bars SB are spaced apart from each other in the first direction D1, respectively. Accordingly, the substrates may be stacked in the first direction D1 in the cassette CAS. The support bars SB may support the substrates, respectively. The support bars SB may prevent the substrates from sagging due to gravity, and may allow the substrates to be accommodated separately from each other. In an embodiment, the support bars SB may include a first group of support bars SB-G1 stacked on each other in the first direction D1 and a second group of support bars SB-G2 stacked on each other in the first direction D1. The first group of support bars SB-G1 may be spaced apart from each other in the first direction D1 to provide a plurality of first spaces. Each first space may be defined by two adjacent support bars of the first group of support bars SB-G1. The second group of support bars SB-G2 may be spaced apart from each other in the first direction D1 to provide a plurality of second spaces. Each second space may be defined by two adjacent support bars of the second group of support bars SB-G2. The first group of support bars SB-G1 may be spaced apart from the second group of support bars SB-G2 at a first distance in the third direction D3. The first distance may be the same as or smaller than a width in the third direction D3 of a substrate to be accommodated in the cassette CAS. The width of the substrate may have a predetermined dimension according to a display device to be manufactured, and the first distance between the first and second group of support bars SB-G1 and SB-G2 may be set according to the width of the substrate. Each of the plurality of first spaces and a corresponding second space of the plurality of second spaces may be positioned at the same height in the first direction D1, and may define a corresponding slot of the plurality of slots SL. A substrate may be inserted into one of the plurality of slots SL and supported by support bars defining the slot. In an embodiment, the plurality of support bars may include a rigid material such as metal and plastic.

The jig JIG for inspecting the cassette may include a first frame FR1, a first fixing member FM1, a second frame FR2, a second fixing member FM2, a first positioning member PM1, and a second positioning member PM2. The jig JIG for inspecting the cassette may extend in the first direction D1.

The first frame FR1 may be parallel to the plane defined by the second direction D2 and the third direction D3. The first frame FR1 may be coupled to the first plate PL1. In an embodiment, the first frame FR1 may be of a plate shape such as a rectangular shape or a square shape. In an embodiment, the first frame FR1 may include or may be formed of a rigid material such as metal and plastic.

The first fixing member FM1 may protrude from a lower surface of the first frame FR1 in a direction opposite to the first direction D1. For example, the first fixing member FM1 may include two protrusion portions, and a portion of the first plate PL1 may be inserted between the protrusion portions. The first fixing member FM1 may be fixed to the first plate PL1. Accordingly, the first frame FR1 may be coupled to the first plate PL1 through the first fixing member FM1. A lower portion of the jig JIG for inspecting the cassette may be fixed to the cassette CAS through the first frame FR1 and the first fixing member FM1. In an embodiment, the first fixing member FM1 may include a pair of protrusions extending parallel each other.

Each of the pair of protrusions may be of a bar shape extending in the third direction D3 and may be spaced apart from each other in the second direction D2. In an embodiment, an outermost first bar of the plurality of first bars PL1-B1 may be locked into the space between the pair of protrusions of the first fixing member FM1. In an embodiment, the pair of protrusions may be attached to the lower surface of the first frame FR1.

The second frame FR2 may be connected to the first frame FR1, and may extend from the first frame FR1 in the first direction D1. For example, a lower end of the second frame FR2 may be connected to an upper surface of the first frame FR1. The second frame FR2 may be coupled to the second plate PL2. In an embodiment, the second frame FR2 may include a vertical bar FR2-VB extending in the first direction D1, a curved bar FR2-CB extending in the first direction, and a plurality of connection bars FR2-KB connecting the vertical bar FR2-VB to the curved bar FR2-CB. The connection bars FR2-KB may be spaced apart from each other in the first direction D1 and extend in the third direction D3. In an embodiment, the vertical bar FR2-VB and the curved bar FR2-CB may be connected with each other at the upper end of the second frame FR2. A lowermost connection bar of the plurality of connection bars FR2-KB may be connected to the upper surface of the first frame FR1. The vertical bar FR2-VB and the curved bar FR2-CB may be connected to the lowermost connection bar and extend in the first direction D1.

The second fixing member FM2 may be coupled to the second frame FR2. For example, the second fixing member FM2 may be coupled to an upper end of the second frame FR2. In addition, the second fixing member FM2 may be movable in the first direction D1 or in the direction opposite to the first direction D1. The second fixing member FM2 may be fixed to the second plate PL2. Accordingly, the second frame FR2 may be coupled to the second plate PL2 through the second fixing member FM2. An upper portion of the jig JIG for inspecting the cassette may be fixed to the cassette CAS through the second frame FR2 and the second fixing member FM2.

When the substrates are stacked in the cassette CAS, the second plate PL2 may deform. In addition, a degree of deformation of the second plate PL2 may vary according to a number, size, or the like of the substrates stacked in the cassette CAS. A level may be used to determine the degree of deformation of the second plate PL2. In this case, since the second fixing member FM2 is movable in the first direction D1 or in the direction opposite to the first direction D1, the second fixing member FM2 may be fixed to the second plate PL2 even when the second plate PL2 is deformed. That is, regardless of the deformation of the second plate PL2, the second frame FR2 may be coupled to the second plate PL2 through the second fixing member FM2.

The first positioning member PM1 may be connected to the first frame FR1, and may extend from the first frame FR1 in the first direction D1. For example, a lower end of the first positioning member PM1 may be connected to the upper surface of the first frame FR1. The first positioning member PM1 may define a groove H penetrating the first positioning member PM1. The groove H may include a moving groove MH and a plurality of fixing grooves FH. In an embodiment, the first positioning member PM1 may include a first side surface to which the second frame FR2 is connected and a second side surface at which the groove H is formed. The first side surface and the second side surface may be opposite to each other in the third direction D3.

The moving groove MH may extend in the first direction D1. The fixing grooves FH may extend from the moving groove MH in the second direction D2 and may be spaced apart from each other in the first direction D1. In an embodiment, the fixing grooves FH may be spaced apart from each other at regular intervals in the first direction D1. In addition, positions of the fixing grooves FH may correspond to positions of the slots SL, respectively. For example, the first positioning member PM1 may define 26 fixing grooves FH, and the cassette CAS may define 26 slots SL. However, the present disclosure is not limited thereto, and the first positioning member PM1 may define 25 or less or 27 or more fixing grooves FH, and the cassette CAS may define 25 or less or 27 or more slots SL.

The second positioning member PM2 may be connected to the first positioning member PM1. The second positioning member PM2 may be connected to the second side surface of the first positioning member PM1. The second positioning member PM2 may be moved to a measurement position. The second positioning member PM2 may be movable along the groove H of the first positioning member PM1. Specifically, the second positioning member PM2 may be movable in the first direction D1 or in the direction opposite to the first direction D1 along the moving groove MH of the first positioning member PM1, and may be moved and fixed to one of the fixing grooves FH. The second positioning member PM2 may include a moving member MV and a measuring member MS.

The moving member MV may be movable in the second direction D2 or in a direction opposite to the second direction D2. That is, the second positioning member PM2 may be movable in the first direction D1 or in the direction opposite to the first direction D1 through the first positioning member PM1, and may be movable in the second direction D2 or in the direction opposite to the second direction D2 through the moving member MV. For example, the moving member MV may include a jog dial which serves to determine the amount of moving the moving member MV in the second direction D2.

The measuring member MS may be coupled to the moving member MV. The measuring member MS may be movable in the second direction D2 or in the direction opposite to the second direction D2 by the moving member MV. The measuring member MS may measure sagging of the substrates accommodated in the cassette CAS. For example, the measuring member MS may include digital vernier calipers. The digital vernier calipers may include a digital indicator that displays a measured value.

When damage occurs to the substrate accommodated in the cassette CAS, a cause of the damage to the substrate may be determined using the jig JIG for inspecting the cassette. In an embodiment, the jig JIG for inspecting the cassette may be detachable from the cassette CAS. When the jig JIG for inspecting the cassette is required, the jig JIG for inspecting the cassette may be coupled to the cassette CAS. In addition, when the jig JIG for inspecting the cassette is not required, the jig JIG for inspecting the cassette may be separated from the cassette CAS.

In addition, the jig JIG for inspecting the cassette may be relatively light. For example, the jig JIG for inspecting the cassette may have a hollow shape. For example, the jig JIG for inspecting the cassette may include a relatively light material. As the jig JIG for inspecting the cassette is lightweight, the jig JIG for inspecting the cassette may be easily detached, transported, or the like.

The cassette module CM according to an embodiment of the present disclosure may include the cassette CAS and the jig JIG for inspecting the cassette that is detachable from the cassette CAS. The first and second frames FR1 and FR2 of the jig JIG for inspecting the cassette may be coupled to the cassette CAS, and the second positioning member PM2 of the jig JIG for inspecting the cassette may be easily moved to the measurement position. When a problem (e.g., substrate damage) occurs in the substrate accommodated in the cassette CAS, the jig JIG for inspecting the cassette may be coupled to the cassette CAS to accurately measure a sagging amount of the substrate. Accordingly, a cause of the problem may be clearly and quickly identified, and reliability and convenience in a process may be improved.

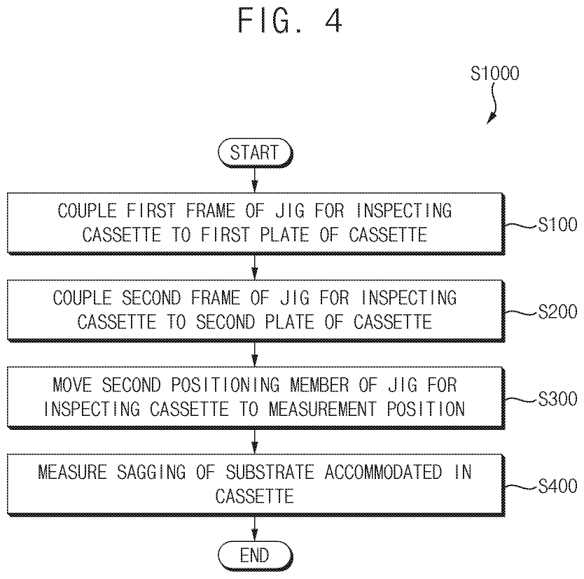

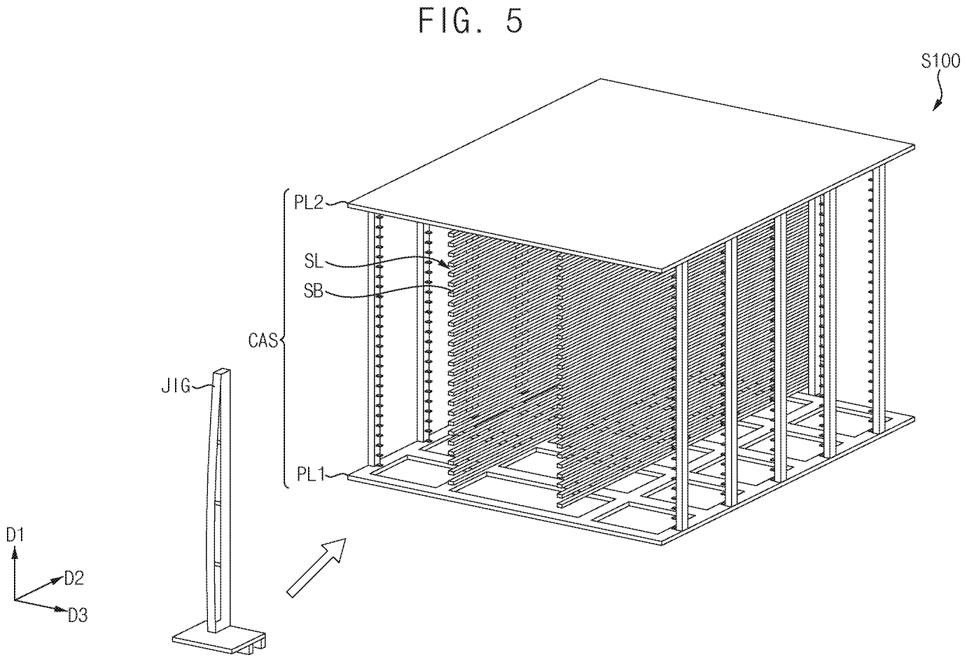

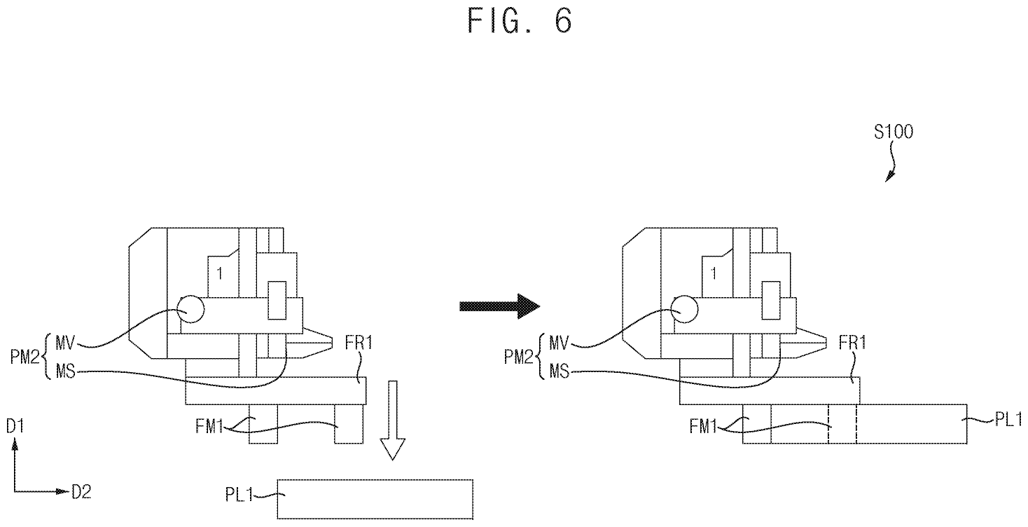

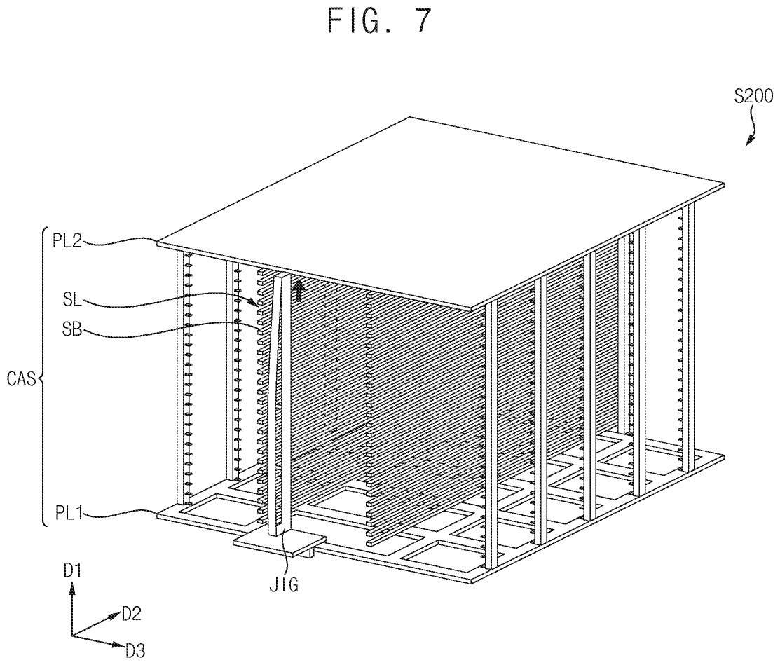

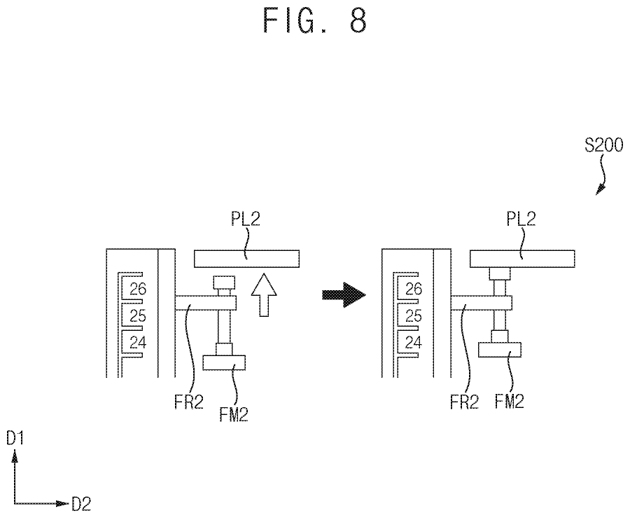

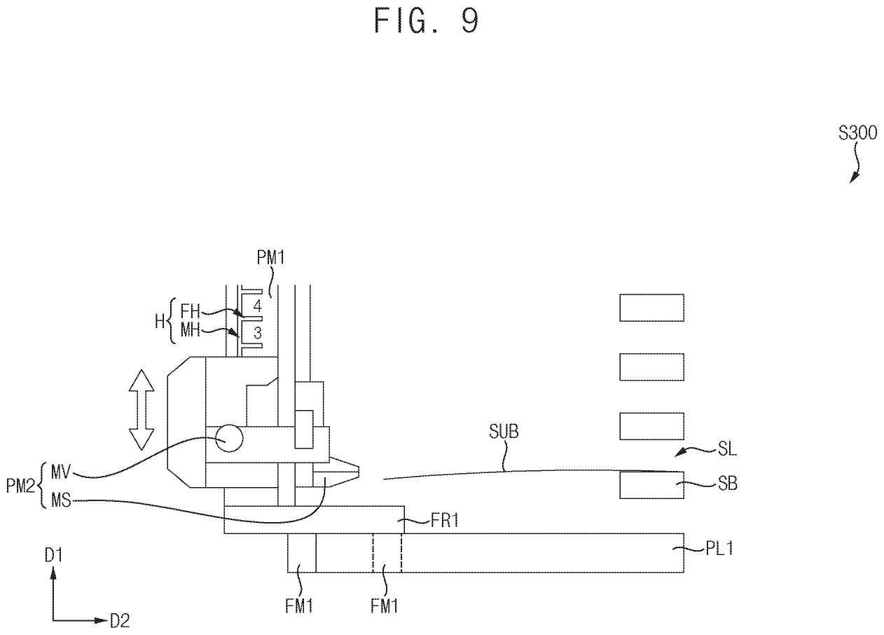

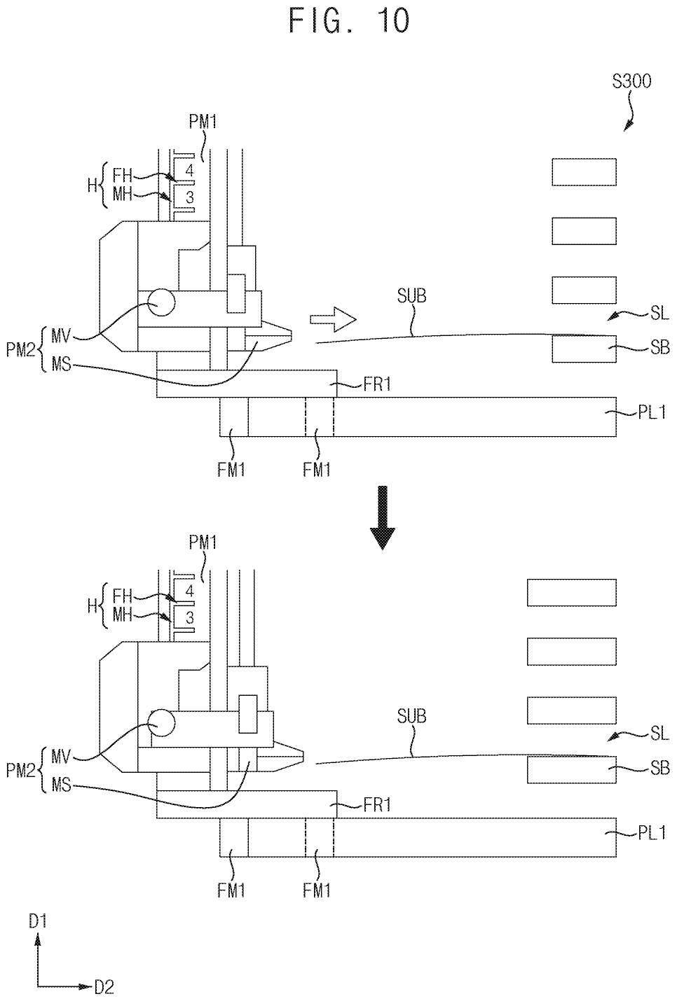

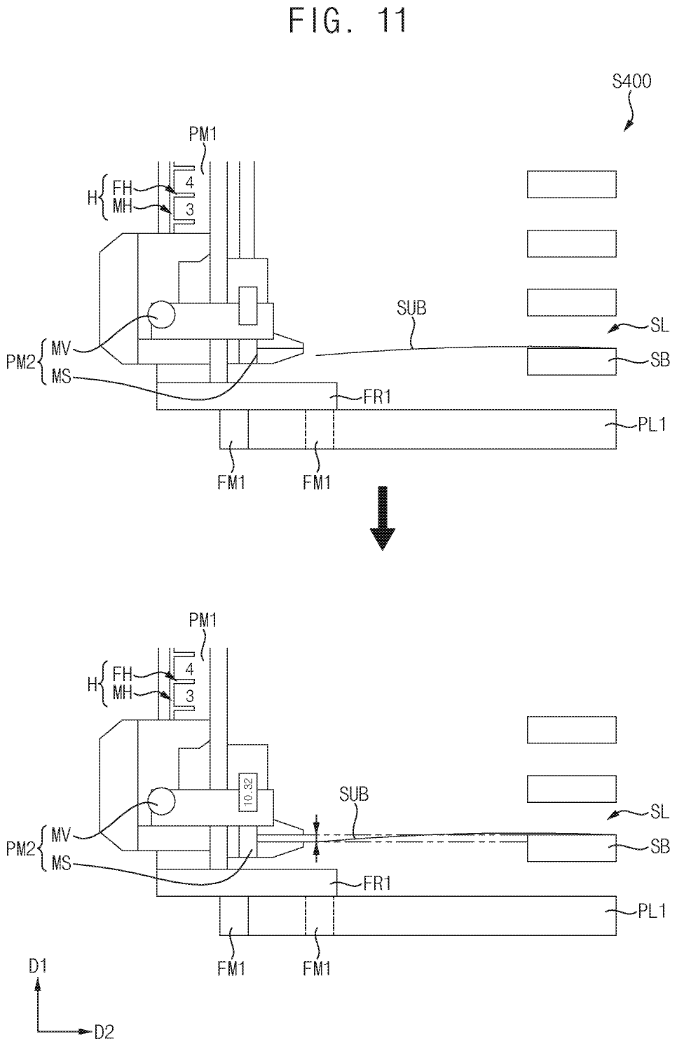

FIGS. 4, 5, 6, 7, 8, 9, 10 and 11 are view illustrating a method of inspecting a cassette according to an embodiment of the present disclosure.

For example, a method (S1000) of inspecting a cassette described with reference to FIGS. 4, 5, 6, 7, 8, 9, 10, and 11 may be performed using the cassette module CM described with reference to FIGS. 1, 2, and 3. Therefore, redundant descriptions will be omitted or simplified.

Referring to FIGS. 1, 2, 4, 5, and 6, in the method (S1000) of inspecting the cassette using the cassette module CM, the first frame FR1 of the jig JIG for inspecting the cassette may be coupled to the first plate PL1 of the cassette CAS (S100).

In the coupling of the first frame FR1 to the first plate PL1 (S100), the first frame FR1 may be coupled to the first plate PL1 through the first fixing member FM1. The first fixing member FM1 may include the protrusion portions protruding from the lower surface of the first frame FR1 in the direction opposite to the first direction D1, and may be fixed to the first plate PL1. Accordingly, the cassette CAS and the jig JIG for inspecting the cassette, which were separated from each other, may be coupled.

Referring to FIGS. 1, 2, 4, 7, and 8, in the method (S1000) of inspecting the cassette using the cassette module CM, the second frame FR2 of the jig JIG for inspecting the cassette may be coupled to the second plate PL2 of the cassette CAS (S200).

In the coupling of the second frame FR2 to the second plate PL2 (S200), the second frame FR2 may be coupled to the second plate PL2 through the second fixing member FM2. The second fixing member FM2 may be coupled to the second frame FR2, and may be moved in the first direction D1 to be fixed to the second plate PL2. In this case, a degree to which the second fixing member FM2 is moved in the first direction D1 may be adjusted according to the degree of deformation of the second plate PL2. Accordingly, the upper portion and the lower portion of the jig JIG for inspecting the cassette may be coupled to the cassette CAS, respectively. The jig JIG for inspecting the cassette may be fixed to the cassette CAS.

Referring to FIGS. 1, 2, 4, 9, and 10, in the method (S1000) of inspecting the cassette using the cassette module CM, the second positioning member PM2 of the jig JIG for inspecting the cassette may be moved to the measurement position (S300).

In the moving of the second positioning member PM2 to the measurement position (S300), the second positioning member PM2 may be moved in the first direction D1 or in the direction opposite to the first direction D1 through the first positioning member PM1. Specifically, the second positioning member PM2 may be moved along the moving groove MH of the first positioning member PM1 and then moved to one of the fixing grooves FH of the first positioning member PM1 to be fixed.

In this case, since the positions of the fixing grooves FH correspond to the positions of the slots SL, respectively, the second positioning member PM2 may be fixed to a fixing groove FH corresponding to a slot SL in which a target substrate SUB, which is a measurement target of the jig JIG for inspecting the cassette, is accommodated among the fixing grooves FH. In an embodiment, the second positioning member PM2 may be fixed to the first positioning member PM1 and may be adjacent to the slot SL in which the target substrate SUB is accommodated. Since the positions of the fixing grooves FH are fixed to correspond to the positions of the slots SL, a movement of the second positioning member PM2 to the fixing groove FH corresponding to the slot SL in which the target substrate SUB is accommodated may be relatively quickly performed.

Next, in the moving of the second positioning member PM2 to the measurement position (S300), the second positioning member PM2 may be moved in the second direction D2 through the moving member MV. That is, the measuring member MS may be moved in the second direction D2 through the moving member MV. The second positioning member PM2 may be moved up to a position of the target substrate SUB, which is the measurement position, in the second direction D2. In an embodiment, the measuring member MS may be moved up to one end of the target substrate SUB in the second direction D2. For example, the measuring member MS may be moved along the second direction D2 by the moving member MV to measure the amount of sagging of the target substrate SUB. In an embodiment, the moving member MV may include a plate to which the measuring member MS is attached and a rail extending along the second direction D2.

Referring to FIGS. 1, 2, 4, and 11, in the method (S1000) of inspecting the cassette using the cassette module CM, the sagging of the target substrate SUB accommodated in the cassette CAS may be measured (S400).

In the measuring of the sagging of the target substrate SUB (S400), the measuring member MS may measure a maximum sagging position of the target substrate SUB. For example, when the measuring member MS includes the digital vernier calipers, the measuring member MS may adjust a lower end of the digital vernier calipers to the maximum sagging position of the target substrate SUB to measure the sagging of the target substrate SUB, and the measured sagging amount may be displayed on the digital indicator.

The cause of substrate damage may be determined by the sagging amount of the target substrate SUB measured by the jig JIG for inspecting the cassette. For example, when the measured sagging amount of the target substrate SUB is about 13 mm or more, it may be determined that the cause of substrate damage is in the cassette CAS. In addition, when the measured sagging amount of the target substrate SUB is about 13 mm or less, it may be determined that the cause of substrate damage is in a configuration other than the cassette CAS such as a transfer robot hand, or the like. However, the present disclosure is not limited thereto, and the sagging amount as a criterion for determining the cause may be variously changed.

The present disclosure can be applied to a manufacturing process of various display devices. For example, the present disclosure is applicable to a manufacturing process of various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A jig for inspecting a cassette, the jig comprising:
a first frame;
a second frame connected to the first frame and extending from the first frame in a first direction;
a first positioning member extending from an upper surface of the first frame in the first direction, wherein the first positioning member includes a first side surface connected to the second frame and a second side surface at which a groove is defined; and
a second positioning member connected to the second side surface of the first positioning member and movable along the groove.

2. The jig of claim 1, further comprising:
a first fixing member protruding from a lower surface of the first frame in a direction opposite to the first direction; and
a second fixing member coupled to the second frame and movable in the first direction or in the direction opposite to the first direction.

3. The jig of claim 1,
wherein the second positioning member includes:
a moving member movable in a second direction intersecting the first direction or in a direction opposite to the second direction; and
a measuring member coupled to the moving member.

4. The jig of claim 1,
wherein the groove includes:
a moving groove extending in the first direction; and
a plurality of fixing grooves extending from the moving groove in a second direction intersecting the first direction and spaced apart from each other along the first direction.

5. A cassette module comprising:
a cassette including a first plate and a second plate spaced apart from the first plate in a first direction and facing the first plate, and defining a plurality of slots between the first plate and the second plate; and
a jig for inspecting the cassette extending in the first direction, and detachably coupled to each of the first plate and the second plate.

6. The cassette module of claim 5,
wherein the jig includes:
a first frame detachably coupled to the first plate; and
a second frame connected to the first frame, extending from the first frame in the first direction, and detachably coupled to the second plate.

7. The cassette module of claim 6,
wherein the jig further includes:
a first fixing member protruding from a lower surface of the first frame in a direction opposite to the first direction, and
wherein the first frame is coupled to the first plate through the first fixing member.

8. The cassette module of claim 6,
wherein the jig further includes:
a second fixing member coupled to the second frame and movable in the first direction or in a direction opposite to the first direction, and
wherein the second frame is coupled to the second plate through the second fixing member.

9. The cassette module of claim 6, wherein the jig further includes:
a first positioning member extending from an upper surface of the first frame in the first direction, wherein the first positioning member includes a first side surface connected to the second frame and a second side surface at which a groove is defined; and
a second positioning member connected to the second side surface of the first positioning member and movable along the groove.

10. The cassette module of claim 9,
wherein the groove includes:
a moving groove extending in the first direction; and
a plurality of fixing grooves extending from the moving groove in a second direction intersecting the first direction, and spaced apart from each other along the first direction.

11. The cassette module of claim 10,
wherein the plurality of fixing grooves are spaced apart at regular intervals along the first direction, and
wherein positions of the plurality of fixing grooves correspond to positions of the plurality of slots, respectively.

12. The cassette module of claim 9,
wherein the second positioning member includes:
a moving member movable in a second direction intersecting the first direction or in a direction opposite to the second direction; and
a measuring member coupled to the moving member.

13. A method of inspecting a cassette, the method comprising:
coupling a first frame of a jig for inspecting the cassette to a first plate of the cassette defining a plurality of slots;
coupling a second frame of the jig to a second plate of the cassette spaced apart from the first plate in a first direction;
moving a positioning member of the jig to a measurement position; and
measuring a sagging of a substrate accommodated in one of the plurality of slots of the cassette using the jig.

14. The method of claim 13,
wherein the jig includes a first fixing member protruding in a direction opposite to the first direction, and
wherein in the coupling of the first frame to the first plate, the first frame is coupled to the first plate through the first fixing member.

15. The method of claim 13,
wherein the jig includes a second fixing member coupled to the second frame and movable in the first direction or in a direction opposite to the first direction, and
wherein in the coupling of the second frame to the second plate, the second frame is coupled to the second plate through the second fixing member.

16. The method of claim 13,
wherein the positioning member includes:
a first positioning member extending in the first direction and defining a groove; and
a second positioning member connected to the first positioning member and movable along the groove, and
wherein the groove includes:
a moving groove extending in the first direction; and
a plurality of fixing grooves extending from the moving groove in a second direction intersecting the first direction, and spaced apart from each other along the first direction.

17. The method of claim 16,
wherein the moving of the positioning member to the measurement position includes:
moving the second positioning member in the first direction or in a direction opposite to the first direction through the first positioning member.

18. The method of claim 17,
wherein the moving of the second positioning member in the first direction or in the direction opposite to the first direction includes:
moving the second positioning member along the moving groove of the first positioning member; and
moving and fixing the second positioning member to one of the plurality of fixing grooves of the first positioning member.

19. The method of claim 17,
wherein the second positioning member includes:
a moving member movable in the second direction or in a direction opposite to the second direction; and
a measuring member coupled to the moving member, and
wherein the moving of the positioning member to the measurement position further includes:
moving the measuring member in the second direction through the moving member.

20. The method of claim 19,
wherein in the measuring of the sagging of the substrate accommodated in the plurality of slots of the cassette using the jig,
the sagging of the substrate is measured through the measuring member.
